(19) United States
(12) Patent Application Publication
(10) Pub. No.: US 2025/0060467 A1
(43) Pub. Date: Feb. 20, 2025

(54) ULTRASONIC PROXIMITY SWITCH

(71) Applicant: ELESTA GmbH Ostfildern (DE) Zweigniederlassung Bad Ragaz, Bad Ragaz (CH)

(72) Inventors: Guido Piai, Gams (CH); Klaus Frick, Satteins (AT); Raphael Möhr, Maienfeld (CH)

(21) Appl. No.: 18/806,965

(22) Filed: Aug. 16, 2024

(30) Foreign Application Priority Data
Aug. 17, 2023 (CH) CH000874/2023

(51) Int. Cl. G01S 7/539; G01S 7/524; G01S 7/527; G01S 7/53; G01S 15/10; H03K 17/945

(52) U.S. Cl. CPC G01S 7/539; G01S 7/524; G01S 7/5276; G01S 7/53; G01S 15/108; H03K 17/945; H03K 2017/9455

(57) ABSTRACT

A device and a method for detecting an actuator by sonicating the actuator with sound waves through a sensor. The device is used in particular in a safety application. The sensor and actuator can be moved relative to each other. The sensor includes a sound wave transmitter, a sound wave receiver and a computing unit. The sound wave transmitter is designed to send sound waves in the direction of the actuator. The sound wave receiver, in turn, is designed to pick up the sound waves reflected by the actuator and convert them into an analog signal. The computing unit converts the analog signal into a digital signal and detects the actuator by comparing it with a reference signal.

### TECHNICAL FIELD OF THE INVENTION

The invention relates to a device for detecting an actuator by means of a sensor according to the general term of claim 1 and a method for detecting an actuator by means of sound waves according to claim 18.

### BACKGROUND OF THE INVENTION

Ultrasonic sensors are used today for measuring distances, for example. The ultrasonic waves are emitted by the transmitter source, hit an obstacle and reflect an echo in the form of ultrasonic waves back in the direction of the sensor, where they are picked up by the at least one receiver. The distance between the sensor and the obstacle is determined using the measured time between sending and receiving the ultrasonic waves. The information thus provided by the ultrasonic sensors is limited to whether an object is present or not and what distance this object is from the ultrasonic sensor. To increase the quality of the measurement, the ultrasonic sensors can have several transmission sources and several receivers.

Ultrasonic sensors are currently used little or not at all in safety applications. One disadvantage of ultrasonic sensors is that they are dependent on the reflected sound waves or the echo and this reacts sensitively to external influences such as temperature. Another disadvantage is the increased complexity of the system for detecting small three-dimensional structures.

The Chinese patent application CN 114758367 discloses a fingerprint identification device arranged under a printing plate. The identification device comprises an ultrasonic unit, a piezoelectric layer, a first electrode located above the piezoelectric layer, and a second electrode located below the piezoelectric layer. The ultrasonic unit is used to send ultrasonic signals to a finger and to receive the ultrasonic detection signal sent back from the finger. Under the ultrasonic unit there is a silicon substrate with a thickness of approx. 50 mm with a switching unit which is used to generate the ultrasonic signal and process the ultrasonic detection signal. A piezoelectric layer with a thickness of between 4 and 20 micrometers is applied to the silicon substrate, which generates a resonant frequency of between 8 and 26 MHz. A connecting layer is advantageously provided between the ultrasonic unit and the pressure plate.

During fingerprint identification, the circuit unit generates an excitation signal and causes the piezoelectric layer to vibrate. The resulting ultrasound signal is transmitted to the finger and reflected. Based on the inverse piezoelectric effect, a potential difference is generated between the first electrode 112 and the second electrode 113 to obtain a corresponding electrical signal. This is processed to obtain the fingerprint pattern of the finger.

GB2529484 discloses an analyzing device having an input for receiving ultrasonic data relating to a contact surface between first and second elements in tribological contact, and an output for outputting data relating to at least one of a contact stress in the first element and a contact load applied to the first element. In a processing section, the ultrasonic data is processed to determine ultrasonic transit time data and derive the output data. Perpendicular to the contact surface, the direction of propagation of the ultrasound has the largest component. Processing to determine ultrasonic transit time data and ultrasonic time of flight is independent of a phase shift that depends on a contact condition at the contact surface.

### TASK

It is therefore a task of the present invention to demonstrate a device for detecting an actuator with the aid of sound waves, which is inexpensive both to manufacture and to use and is robust against the sensitivity of the sound wave sensors to external influences and to changes in the actuators to be detected.

### DESCRIPTION

The problem is solved with a device for detecting an actuator by sonicating the actuator with sound waves by means of a sensor with the features of claim 1.

The device is used in particular as an ultrasonic proximity switch in a safety application. The sensor can be moved relative to the actuator and comprises at least one sound wave transmitter, at least one sound wave receiver and at least one computing unit. The sound wave transmitter is designed to send sound waves in the direction of the actuator. The sound wave receiver, in turn, is designed to pick up the sound waves reflected by the actuator and convert them into an analog signal. The computing unit converts the analog signal into a digital signal and detects the actuator by comparing it with a reference signal.

The computing unit has a reference signal stored in a memory, which is usually assigned to a specific actuator. The sensor is designed to emit sound waves and receive the reflected sound waves in turn. By comparing the reflected sound waves with the reference signal already stored in the computing unit, the computing unit can determine whether the sound waves have been reflected by the actuator associated with the reference signal. The device can use the sensor and the signal received by it to detect and, if necessary, identify the sonicated actuator. The device makes it possible to determine whether the actuator is in a certain position opposite the sensor. The actuator can either be in contact with the sensor or at a certain distance from the sensor. When used in a safety application, the interaction between sensor and actuator has a safety-relevant function. The successful detection of the actuator, so that the sensor can determine with the help of the computing unit whether the taught-in actuator is at the intended location or not, can be equated with ensuring the safety of a system. For example, the closing status of a door or window can be monitored using this device. The actuator can be positioned in the door or window while the sensor is positioned in the frame, or vice versa. Only when the door or window is completely closed and the distance between the door or window and the frame is minimal does positive detection of the actuator take place, which in turn is equated with the closed state of the door or window.

The reference signal contains the information for detecting an actuator. The requirement for the reference signal is that it must allow a comparison with the measured signal. The reference signal can be stored in the computing unit in any form, which means that the type or form of the reference signal has no limiting effect on the subject of the invention. It is conceivable that the reference signal is in the form of a time function, a table or a diagram, wherein this is a non-exhaustive list of data reproduction options. The reference signal must ideally contain at least the correlation between time and amplitude.

The stored reference signal or one or more copies of it can be adapted to the changing ambient conditions. For this purpose, a copy of the reference signal could be renewed at the recognized, identified and applied actuator at predefined intervals or based on other criteria.

When the reflected sound waves are matched again, both the original and the renewed reference signals are used.

Preferably, the actuator has a three-dimensional pattern from which the sound waves are reflected and changed. This makes it possible to realize different actuators with a similar structure, wherein they differ from each other only by the three-dimensional pattern. At the same time, the three-dimensional pattern helps to determine the identification of an actuator more reliably, in that the first three-dimensional pattern shows a clear deviation from the three-dimensional patterns of the other actuators, which in turn increases the reliability and tamper protection of the actuator identification.

The sensor preferably comprises two computing units, each of which has access to a reference signal. In principle, these can perform the conversion to a digital signal independently, or only an analog-to-digital transducer can be provided. The use of two calculation units can serve as a control, in that further steps are only carried out if both calculation units show the same result with regard to the agreement of the measured signal with the reference signal. The conversion by the two computing units can also be carried out independently of each other in different ways, e.g., with different analog/digital transducers (A/D transducers), integrated in the microcontroller (MCU) or externally as a dedicated component. Differences can also be achieved with the sampling frequency. This increases the safety of the conversion function into a digital signal during operation.

The sound waves emitted by the sensor reach the three-dimensional pattern via the forward path and travel the same path in the opposite direction after being reflected by the pattern. The forward path between the sensor and the pattern has a minimum length adapted to the sensor. The lower limit of the forward path is used to ensure that a certain time elapses after the sound waves are emitted by the sensor until the reflected waves are received by the receiver. The time duration also has a lower limit, which must not be undercut if the transmitter and receiver are formed by the same component. In one such embodiment, the membrane used to generate the sound waves is also used to receive the reflected waves. The minimum time is defined by the time it takes for the membrane to return to its resting state after excitation.

The actuator preferably has a contact surface for the sensor, wherein the three-dimensional pattern is arranged in the actuator and at a distance from the contact surface. The distance between the pattern (coding) and the contact surface must be at least equal to the forward path. The actuator can be designed to make contact with the sensor. This contact should preferably be made via the contact surface of the actuator. This enables a favorable introduction of the sound waves from the sensor into the actuator and from the actuator back into the sensor. The ultrasonic transducer of the sensor makes contact with the actuator, preferably at the intended contact surface. The pattern of the actuator is then located inside the actuator after the forward path—i.e., opposite or at a distance from the contact surface. By arranging the three-dimensional pattern opposite the contact surface, the distance between the pattern and the contact surface is maximized.

In a preferred embodiment of the device, the actuator is arranged opposite the sensor in such a way that when the actuator and the sensor come into contact, or when the sensor and the actuator are at the minimum required distance from each other, the sound wave transmitter of the sensor is directed towards the pattern of the actuator. The sensor is used to detect the actuator and its three-dimensional pattern. In certain applications, it may be sufficient if the detection of the actuator is only realized when the sensor is in contact with the actuator or the distance between the sensor and the actuator is minimal. This reduces the window in which detection of the actuator by the sensor is possible and thus leads to a higher safety hurdle when using the device in a safety application. It is only possible to detect the actuator if the sensor and the actuator are as close together as possible.

In a further preferred embodiment, the sound wave transmitter and the sound wave receiver must be in contact with the contact surface of the actuator in order to detect the actuator. This means that the sensor must be in contact with the actuator in order to successfully detect the actuator. In use, this feature ensures that the door is closed without gaps. As soon as the door is open a small gap and the safety of a system is no longer guaranteed, for example, this can be detected by the sensor.

The sound wave receiver prefers to pick up the reflected sound waves in their entirety. Recorded in their entirety means that the sound wave receiver receives the reflected sound waves locally at one point and converts them into a single signal. This allows the device to function with just one sensor, which simplifies production, reduces space requirements and minimizes costs.

The computing unit has the task of creating the comparison between the received signal and the reference signal. The processing speed of the processing unit for creating this adjustment is fastest if the processing unit has the most direct possible access to the reference signal. Preferably, the reference signal is stored in the computing unit. This provides the computing unit with the most direct access to the reference signal. A fast processing speed of the computing unit can be particularly important for safety applications.

Ideally, the pattern of the actuator has a three-dimensional structure. A three-dimensional structure has the advantage that the sound waves undergo a distinctive change when reflected, which makes it easier to infer the actuator from the reflected sound waves. At the same time, a three-dimensional structure offers a greater variety of modification options for creating different three-dimensional patterns.

In a further preferred embodiment, the pattern comprises two surfaces facing the contact surface of the actuator, which each have a different distance from the contact surface. The division of the pattern into two surfaces, each at a different distance from the contact surface, forms a three-dimensional structure. At the same time, the division into two surfaces with different distances to the contact surface creates a simple construction with a large number of possible variations by changing the distance to the contact surface of one or both surfaces.

As already mentioned above, the reflected sound waves are preferably received and evaluated in their entirety, which are reflected by the two surfaces of the pattern. The evaluation of the sound waves in their entirety also brings advantages when designing the pattern. This means that the difference between the distance between the two surfaces and the contact surface can be very small. Preferably, the difference between the distances of these two surfaces is less than 1 mm, preferably less than 0.5 mm, even more preferably less than 0.3 mm, but more than 0.01 mm and preferably more than 0.05 mm.

Advantageously, the computing unit recognizes the pattern of the actuator by comparing it with a reference signal. The calculation unit is responsible for creating a comparison between the measured signal and the reference signal.

The computing unit is responsible for recognizing the actuator. Preferably, the computing unit generates a binary signal based on the detection of the actuator. The binary signal allows a statement to be made as to whether the actuator is present at the transmitter/receiver or not, for example. This in turn can be of great importance for safety-relevant applications, as the device makes a statement that describes a clear status of the device. For example, such a condition could be a closed safety door.

In a further preferred embodiment, the computing unit generates a switch-off signal if the actuator is not successfully detected. Generating a switch-off signal is usually very important for safety applications. Detection of the actuator is the basic state in which safety is guaranteed. As long as the actuator is detected, the safety of the system is guaranteed. The need to detect a hazardous situation as quickly as possible and forward it to a control unit can be met by generating the switch-off signal as quickly as possible. The generation of a switch-off signal by the computing unit leads to a very fast reaction to any changes in the assignment between the transmitter and the actuator.

Ideally, the sound wave transmitter and the sound wave receiver are arranged at the same location, in particular they use the same membrane for transmitting and receiving sound waves. This means that the point of origin of the sound waves coincides with the point of reception of the reflected sound waves. As a rule, the reflected sound waves are received from the direction in which the sound waves are emitted. By arranging the transmitter and receiver in the same place, the sensor can have a compact design. If, in addition, the same membrane is used by the transmitter and receiver, an element such as a transducer can also be used, which comprises a transmitter and a receiver. The use of the same membrane for the transmitter and receiver results in lower manufacturing costs for the sensor and thus for the entire device. Preferably, a piezoelectric ultrasonic transducer is used, which can be used both as a transmitter and as a receiver.

Preferably, the sound wave transmitter generates sound waves with a frequency of 300 kHz to 20 MHz, preferably between 350 kHz and 8 MHz, and particularly preferably between 1 and 4 MHz. Only ultrasonic waves fall within this range. The use of this frequency range does not cause any unwanted pollution of the environment.

The actuator is preferably made of plastic. Preferably, a plastic with a low sonic velocity that remains constant over the temperature, such as POM (polyoxymethylene), is used. Preferably, a plastic is used in which the sound propagation is less than 2500 m/s and the influence of the temperature change is less than 2 m/s per degree Celsius. The advantage of plastic is that it is favorable in the production of complex shapes and structures, such as those that can occur in the actuator pattern. At the same time, plastic has the necessary property of reflecting the sound waves so well that they can be received and evaluated in their entirety.

A further aspect of the invention relates to a method for detecting an actuator using sound waves. The sound waves are emitted by a sound wave transmitter and picked up by a sound wave receiver. The method comprises transmitting sound waves to a pattern of the actuator and receiving the sound waves reflected by the pattern of the actuator by the sound wave receiver. The sound waves received are converted into an electrical signal. Furthermore, a comparison of this signal by the computing unit with a reference signal stored therein and the generation of a binary signal as a result of the comparison by the computing unit and determination of the detection of the actuator on the basis of the binary signal is provided for in the method according to the invention. Comparing the measured signal with the reference signal makes it possible to determine the correspondence between the two signals. If the match shows a predefined similarity, the sonicated actuator is positively recognized as a taught-in reference actuator. This means, for example, that a statement can be made as to whether the taught-in (reference) actuator is present at the sensor or not. Advantageously, the reflected sound waves are picked up in their entirety by the sound wave receiver. This means that a single sound wave receiver picks up the reflected sound waves and forms a single measurement signal based on the reflected and received sound waves. This makes it possible to design the sensor as simply as possible, as the sensor only needs to have a sound wave transmitter and a sound wave receiver.

Preferably, the reference signal is generated in a first step by teaching the actuator. Teach-in of the actuator describes the execution of a reference measurement. For this purpose, the actuator is placed at the target position and sonicated by the sensor. The receiver in the sensor picks up the reflected sound waves and generates a signal based on the measured sound waves, which forms the reference signal. The reference signal can therefore be understood as an image of the taught-in actuator.

The method is preferably used in a safety application, wherein a warning or switch-off signal or a safety withdrawal is generated if the actuator is not successfully detected. This method can be used to check whether the actuator is in the intended location or not and whether it is the taught-in actuator or not, making it ideal for use in safety applications. The status of a door or window can be reliably monitored using such a method and a warning or shut-off signal can be generated immediately if the door or window is opened. Another advantage in this respect is the high sensitivity of the method according to the invention. The reflected sound waves deviate very quickly from the reference signal if, for example, the actuator is only slightly offset from the original state, i.e., in the range between 0.1 and 1 mm. The high sensitivity of the method results in a small tolerance for the device to be monitored, which in turn leads to precise testing or monitoring of the device to be monitored.

Advantageously, the actuator has a contact surface and the sound wave transmitter is in contact with this contact surface to detect the actuator. When the sound wave transmitter is in contact with the contact surface of the actuator, the sound waves only propagate in the housing of the actuator. This means that there are no disturbing influences from the environment on the sound waves and their measurement, such as different distances between the actuator and the sensor or the condition of the air between the actuator and the sensor. The provision of a contact surface enables interference-free measurements, provided there is perfect contact between the sensor and actuator.

Preferably, the sound wave transmitter emits sound waves perpendicular to the contact surface. This makes the most efficient use of the volume of the actuator, which in turn allows better differentiation between the reflected sound waves.

The aforementioned optional features can be realized in any combination, as long as they are not mutually exclusive. In particular where preferred ranges are specified, further preferred ranges result from combinations of the minima and maxima specified in the ranges.

### BRIEF DESCRIPTION OF THE FIGURES

The invention is described in more detail below with reference to the figures in schematic form. It shows a schematic representation that is not true to scale:

FIG. 1: a sectional view of a device according to the invention with a sensor comprising a sound wave sensor and a sound wave receiver and an actuator;

FIG. 2: a side view of an actuator;

FIG. 3: six diagrams with comparison of measurement signals from six actuators to a reference signal; and

FIG. 4: Diagram with a correlation curve for different actuators.

### DETAILED DESCRIPTION OF THE FIGURES

In the following, identical reference numbers stand for identical or functionally identical elements (in different figures). An additional apostrophe can be used to differentiate between similar or functionally identical or functionally similar elements in a further version.

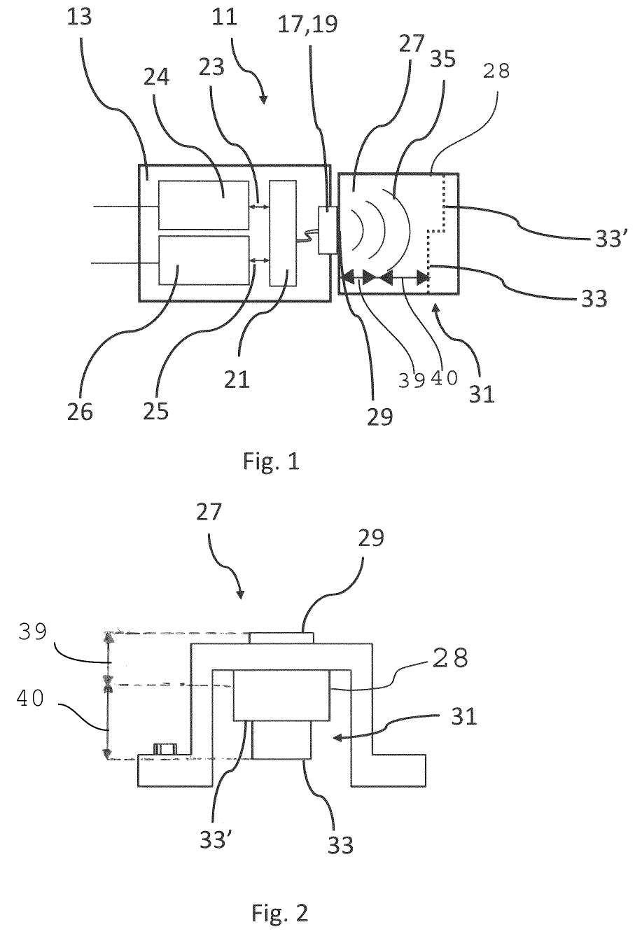

FIG. 1 shows a view of a device 11 consisting of two separate components. The first component is a sensor 13. The sensor 13 comprises a sound wave transmitter 17 and a sound wave receiver 19, which are connected to an analog front end 21. Two channels 23, 25 lead from the analog front end 21 to the outside. The channels 23, 25 each have a computing unit 24, 26. The sound wave transmitter 17, also referred to as the transmitter for short, and the sound wave receiver 19, also referred to as the receiver for short, are attached to a front side of the sensor 13 at approximately the same position. The transmitter and the receiver can also be the same component, in which case the difference between the transmitter and the receiver is only in the function of transmitting and receiving the sound waves. Preferably, a piezoelectric sensor is used as the sound wave transducer, which is operated at a frequency between 300 kHz and 20 MHz.

The second component is formed by an actuator 27. In FIG. 1, the actuator 27 is in contact with the transmitter 17 and receiver 19. The side with which the actuator 27 is in contact with the transmitter 17 and receiver 19 is the contact surface 29 of the actuator. A pattern 31 is provided in the actuator 27 on the side opposite the contact surface 29 and at a distance from it. In the example shown in FIG. 1, the pattern 31 is formed by a gradation. Thus, the pattern 31 has two surfaces 33, 33′ which face the contact surface 29 and are parallel to each other and to the contact surface. The two surfaces 33, 33′ differ in their distance from the contact surface 29. The difference can be between 0.05 and 3 mm, preferably between 0.1 and 2 mm, and particularly preferably between 0.5 and 1.5 mm.

The transmitter 17 is intended to emit sound waves 35 in the direction of the actuator 27. If the actuator 27 is in contact with the transmitter 17, the sound waves 35 emitted by the transmitter propagate through the actuator to the pattern 31. The pattern 31 of the actuator limits the propagation of the sound waves in the actuator. The sound waves 35 hit the pattern 31 and are reflected by it. The reflected sound waves 35 in turn travel the same path in the opposite direction and reach the receiver 19. The receiver 19 has a membrane which is set into vibration by the reflected sound waves. The vibration of the receiver's membrane is recorded as an analog signal. The analog signal can be further processed in the analog receiving circuit (front end) 21, for example by amplifying or filtering it. After processing in the front end 21, the analog signal is forwarded to the respective computing units 24, 26 in the two evaluation channels 23, 25.

The two computing units 24, 26 each have a memory in which a reference signal is stored. After receiving the electrical signal from the receiver, each computing unit 24, 26 compares it with the stored reference signal and determines the similarity or the degree of correspondence between the two signals. If the match exceeds a certain degree or value, this means that the previously taught-in actuator 27 is present at the sensor.

The reference signal can be generated in different ways. One option is to carry out a reference measurement to generate the reference signal before commissioning the device. For this purpose, the actuator 27 is guided to the sensor so that the transmitter 17 and receiver 19 of the sensor come to rest on the contact surface 29 of the actuator. The sonication of the actuator 27 causes a signal at the receiver 19, which is forwarded to the computing units 24, 26 and stored by these as a reference signal after optional signal processing. The actuator 27 is thus read in by the sensor 13 with this reference measurement.

FIG. 2 shows a possible structure of an actuator 27 which is suitable for the device according to the invention. According to the exemplary embodiment shown, the actuator comprises a housing 28 in which a three-dimensional pattern 33, 33′ is integrated. In principle, however, it is also possible to manufacture the actuator from a solid material in which the three-dimensional pattern is embedded. In the present case, the housing of the actuator is designed as a cylinder with a stepped base surface 33, 33′, wherein the cylinder can be designed as a hollow or solid cylinder.

One side of the actuator serves as contact surface 29. The side opposite the contact surface 29 serves as pattern 31. The distance between the contact surface 29 and the pattern 31 is divided into two paths, a so-called forward path 39 and a variable path 40. The forward path 39 is adjacent to the contact surface 29 and has the same length for all actuators 27. The variable path 40 forms the section from the forward path 39 to pattern 31. The forward path 39 is a minimum dimension for the distance between the contact surface 29 and the pattern 31.

It is possible to manufacture further actuators 27, which each have different distances, i.e., variable paths 40, between the pattern surfaces 33 and the contact surface 29 and accordingly each generate a different reflection of the sound waves 35, which in turn leads to a different signal.

The sound waves 35 are picked up by the receiver in their entirety and transmitted as an analog signal. The analog signal can be processed in the analog front end 21 to simplify the comparison between the signals. The amplitude of the signal is plotted as a function of the measurement time, thus forming a time function of the signal. An actuator 27 is detected by matching the function of the signal created in this way. The adjustment generally takes place by comparing the measured signal 41 with a reference signal 43. The reference signal can be generated in different ways.

A first method for generating the reference signal 43 is to calculate an average value, for which each data point of the measurement series is averaged over several measurement series. The selection of measurements for calculating the mean value can be kept variable so that the measured values obtained are continuously included in the calculation of the mean value when measurements are carried out. The formats of the measured signal 41 and the reference signal 43 must match in such a way that both signals can be compared. To ensure this, the signals can be subjected to digital signal processing. The reference signal 43 can then be compared with a measured signal 41, for example by means of a correlation or cross-correlation. The cross-correlation is used to calculate a number that shows the shift between the two signal functions. If this number is close to zero, the actuator has matched. In order to generate a binary output, a limit value can be defined for the result of the cross-correlation, below which the actuator is considered correctly recognized. An alternative method to cross-correlation is to use the mean square error method, in which the sum of the mean square deviation is formed. The smaller this sum is, the more similar the compared functions or signal curves are. To detect an actuator 27, a limit value for the sum of the square deviation must be defined here. If the result is below this limit, there is a similarity and the actuator is recognized as positive. The reference signal and the measured signal are usually available in a normalized state before the adjustment is carried out.

An alternative approach to the first method described above for creating a comparison with a reference signal is the use of artificial intelligence. Training data is read into a neural network to recognize an actuator. This training data must first be generated. For this purpose, the number of all different actuators 27 is produced, which are read in by the sensor 13 and whose signal is stored in a database. The measurement of the read-in actuators 27 by the sensor 13 can take place under different boundary conditions, so that, for example, the influence of the contact surface 29 and the contact between the sensor 13 and the actuator 27 can be included in the training data. The data is divided into several classes, wherein the number of classes is equal to the number of different actuators plus one. The additional class is a class to which every signal that does not fit into one of the actuator classes is assigned. This means that each signal recorded by the sensor is assigned to a class. The computing unit 24 is responsible for assigning the received signals 41 to the respective class. The computing unit 24 uses an artificial neural network or other Al methods that have been trained with training data and have developed a classification mechanism. The assignment of the received signals 41 to the respective class falls under the comparison of a received signal 41 with a reference signal 43.

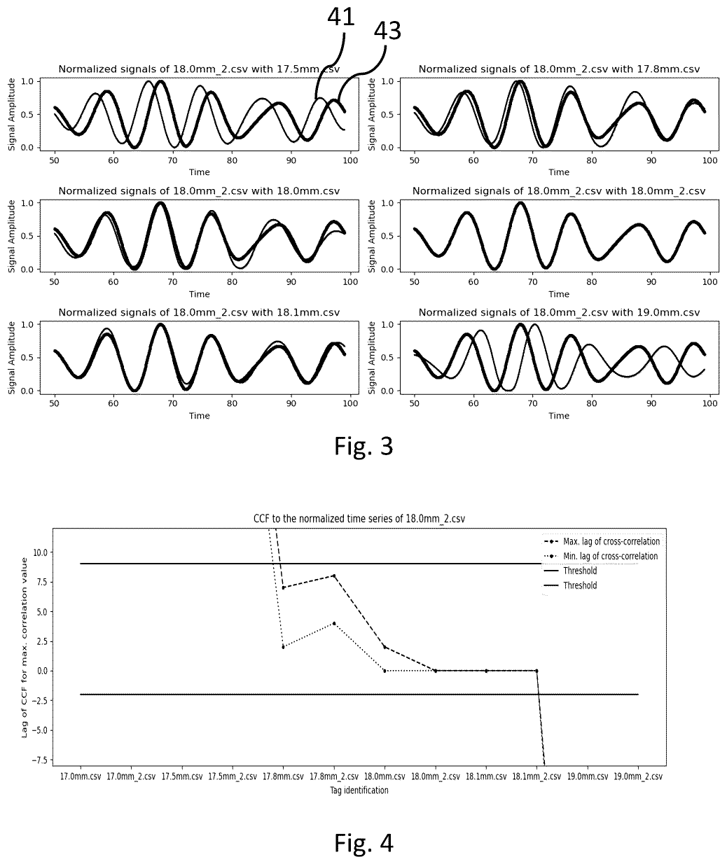

FIGS. 3 and 4 show diagrams with which the above-mentioned correlation can be formed and the actuator 27 can be detected. FIG. 3 shows six diagrams, in each of which a measured signal 41 from a specific actuator is plotted together with a reference signal 43. The reference signal 43 is shown by a thick line, while the measured signal 41 is formed by a thin line. In this example, the reference signal 43 is formed with an actuator 27 with a single coding depth of 18 mm. The six diagrams show the reflected sound waves recorded by the receiver 19 and forwarded to the computing unit 24 in a normalized state for actuators 27 with a coding depth of 17.5 mm, 17.8 mm, 18 mm, 18.1 mm, and 19 mm. Two series of measurements were tested for the coding depth of 18 mm. FIG. 4 shows the maximum and minimum correlation value between the measurement signal 41 and the reference signal 43 for the different actuators 27. On the X-axis of the diagram in FIG. 4, the actuators 27 are plotted with increasing coding depth, while the Y-axis shows the correlation value. An upper and a lower limit value are defined for the correlation value, which are represented in the diagram by two horizontal lines. The results in FIG. 4 show that the correlation for those actuators with a coding depth of 17.8 mm to 18.1 mm is within the limit values. In comparison, the reference signal 43 is formed with an actuator 27 with a coding depth of 18 mm.

Another possible method in this or a similar embodiment for matching the measurement signal 41 with a reference signal 43 is to form the difference signal between these two signals. In contrast to the previous approach, in which several actuators were assigned to different classes, a binary classification is sought by forming the difference signal or other methods. This means that the result is a binary statement as to whether or not the measurement signal 41 matches the reference signal 43 sufficiently. If there is a complete match, the measurement signal 41 is equal to the reference signal 43 and the difference between the two signals is zero. If the reference actuator is sonicated, the difference between the two signals may deviate from zero. For this reason, a tolerance range is defined in the form of a threshold for the difference in which the detection of the reference actuator is still considered positive. Binary classification is only used to detect a single actuator, as this allows a statement to be made as to whether this single actuator is in the same position at the time of the measurement as it was during the reference measurement. In a safety application, for example, it can be used to check the closing status of a door.

The proximity switch is operated as follows: Sound waves are emitted by exciting the ultrasonic transducer with two pulses for a predetermined first period of time, which is between 0.25 ms and 5 ms depending on the operating frequency of the ultrasonic transducer. The reflected sound waves are then detected for a predetermined second period of time, which is between 0 ms and 200 ms. Preferably, the detection of the reflected sound waves is only started between 30 ms and 60 ms after transmission so that the decay of the ultrasonic transducer after excitation by the control pulses is not included in the measurement. The current measurement window is between 55 ms and 95 ms of the received echo.

While specific embodiments have been described above, it is apparent that different combinations of the disclosed embodiments can be used, insofar as the embodiments are not mutually exclusive.

Abstract: Shown and described is a device and a method for detecting an actuator by sonicating the actuator with sound waves through a sensor. The device is used in safety applications in particular. The sensor and actuator can be moved relative to each other. The sensor comprises a sound wave transmitter, a sound wave receiver and a computing unit. The sound wave transmitter is designed to send sound waves in the direction of the actuator. The sound wave receiver, in turn, is designed to pick up the sound waves reflected by the actuator and convert them into an analog signal. The computing unit converts the analog signal into a digital signal and detects the actuator by comparing it with a reference signal.

### REFERENCE LIST

11 Device
13 Sensor
17 Sound wave transmitter
19 Sound wave receiver
21 Analog front end
23 First channel
24 First computing unit
Second channel
26 Second computing unit
27 Actuator
28 Housing
29 Contact surface
31 Pattern
33 Reflection surface of the pattern
Sound waves
39 Forward path
Variable path
41 Measured signal
43 Reference signal

1.-22. (canceled)

23. A device for detecting an actuator by sonicating the actuator with sound waves by a sensor, in particular in a safety application, wherein
the sensor and the actuator are movable relative to each other,
the sensor comprises a sound wave transmitter, a sound wave receiver and a computing unit, wherein the sound wave transmitter and sound wave receiver can be realized as a single component, and
the sound wave transmitter is intended to transmit sound waves in the direction of the actuator and the sound wave receiver is intended to pick up the sound waves reflected by the actuator and convert them in-to an analog signal,
wherein,
the computing unit converts the analog signal into a digital signal and implements the detection of the actuator by comparison with a reference signal.

24. The device according to claim 23, wherein the actuator has a pattern from which the sound waves are reflected and changed.

25. The device according to claim 23, wherein the sensor comprises two computing units which each have a reference signal.

26. The device according to claim 24, wherein the actuator has a contact surface for the sensor, wherein the pattern is arranged at a distance from the contact surface.

27. The device according to claim 24, wherein the actuator is arranged opposite the sensor in such a way that when there is contact or the smallest possible distance between the sensor and the actuator, the sound wave transmitter of the sensor is directed towards the pattern of the actuator.

28. The device according to claim 24, wherein the sound wave transmitter and the sound wave receiver for detecting the actuator rest on the contact surface of the actuator.

29. The device according to claim 23, wherein the sound wave receiver picks up the reflected sound waves in their entirety.

30. The device according to claim 23, wherein the reference signal is stored in the computing unit.

31. The device according to claim 24, wherein the pattern of the actuator has a three-dimensional structure.

32. The device according to claim 26, wherein the pattern comprises two surfaces facing the contact surface of the actuator, each of which has a different distance from the contact surface.

33. The device according to claim 32, wherein the difference between the distances of these two surfaces is less than 1 mm.

34. The device according to claim 24, wherein the computing unit infers the pattern of the actuator by comparison with a reference signal.

35. The device according to claim 23, wherein the computing unit generates a binary signal based on the detection of the actuator.

36. The device according to claim 23, wherein the computing unit generates a switch-off signal if the actuator is not successfully detected.

37. The device according to claim 23, wherein the sound wave transmitter and the sound wave receiver are arranged at the same location, in particular use the same membrane for transmitting and receiving sound waves.

38. The device according to claim 23, wherein the sound wave transmitter generates sound waves with a frequency of 300 kHz to 20 MHz.

39. The device according to claim 23, wherein the actuator is made of a plastic material which is characterized by a low sonic velocity and a low temperature dependence thereof.

40. A method for recognizing an actuator with the aid of sound waves which are transmitted by a sound wave transmitter and received by a sound wave receiver, comprising the following steps;
transmitting sound waves to a pattern of the actuator,
receiving the sound waves reflected by the pattern of the actuator by a sound wave receiver,
converting the sound waves into an electrical signal,
comparison of this signal by a computing unit with a reference signal stored therein,
generation of a binary signal as a result of the comparison by the computing unit and determination of the detection of the actuator on the basis of the binary signal.

41. The method according to claim 40, wherein in a first step the reference signal is generated by teaching-in the actuator.

42. The method according to claim 40, wherein the method is used in a safety application and a warning signal or a safety withdrawal is generated if the actuator is not successfully detected.

43. The method according to claim 40, wherein the actuator has a contact surface and the sound wave transmitter bears against this contact surface to detect the actuator.

44. The method according to claim 43, wherein the sound wave transmitter transmits sound waves directed essentially perpendicularly to the contact surface.
